(19) United States
(12) Patent Application Publication
(10) Pub. No.: US 2026/0139153 A1
(43) Pub. Date: May 21, 2026

(54) SLURRY COMPOSITION AND METHOD OF MANUFACTURING SEMICONDUCTOR PACKAGE USING THE SAME

(71) Applicant: Samsung Electronics Co., Ltd., Suwon-si (KR)

(72) Inventors: Junghun Kim, Suwon-si (KR); Sanghuck Jeon, Suwon-si (KR); Hojin Jeong, Suwon-si (KR); Youngkwan Seo, Suwon-si (KR)

(21) Appl. No.: 19/317,591

(22) Filed: Sep. 3, 2025

(30) Foreign Application Priority Data
Nov. 20, 2024 (KR) 10-2024-0166611

(51) Int. Cl. C09G 1/02; H01L 21/56

(52) U.S. Cl. CPC C09G 1/02; H10W 74/01

(57) ABSTRACT

Provided is a slurry composition used for polishing a polymer-containing film, the slurry composition including a metal ion, a cationic chemical, a nonionic polymer, and abrasive particles. Slurry compositions used for surface treatment of a polymer-containing film by a chemical mechanical polishing (CMP) process are provided comprising a metal ion, a cationic chemical, a nonionic polymer, a pH adjuster, a biocide, water, and abrasive particles. Methods of manufacturing semiconductor packages utilizing slurry compositions of the disclosure are also provided.

### CROSS-REFERENCE TO RELATED APPLICATION

This application is based on and claims priority under 35 USC § 119 to Korean Patent Application No. 10-2024-0166611, filed on Nov. 20, 2024, in the Korean Intellectual Property Office, the disclosure of which is incorporated by reference herein in its entirety.

### TECHNICAL FIELD

The disclosure relates to a slurry composition and a method of manufacturing a semiconductor package by using the same, and more specifically, to a slurry composition for polymer polishing and a method of manufacturing a semiconductor package by using the same.

### BACKGROUND

In recent semiconductor packaging manufacturing processes, the use of polymer-containing films has been increasing. Accordingly, the polishing processes of polymer-containing films are also on the rise. Meanwhile, as the polishing processes for polymer-containing films increase, there is a demand for slurry compositions that may be used in these polishing processes.

### SUMMARY

The inventive concept provides a slurry composition capable of increasing the polishing rate of a polymer-containing film and improving the polishing selectivity between the polymer-containing film and a surrounding insulating film and metal-containing film.

According to an aspect of the inventive concept, there is provided a slurry composition used for polishing a polymer-containing film, the slurry composition including a metal ion, a cationic chemical, a nonionic polymer, and an abrasive particle.

According to another aspect of the inventive concept, there is provided a method of manufacturing a semiconductor package, including forming a gap fill film covering a first semiconductor chip and a plurality of second semiconductor chips horizontally spaced apart from each other on the first semiconductor chip, applying a slurry composition to the gap fill film, and polishing the gap fill film, wherein the gap fill film is a polymer-containing film, and the slurry composition includes a metal ion, a cationic chemical, a nonionic polymer, and an abrasive particle.

According to another aspect of the inventive concept, there is provided a slurry composition used for surface treatment of a polymer-containing film by a chemical mechanical polishing (CMP) process, the slurry composition including a metal ion, a cationic chemical, a nonionic polymer, a pH adjuster, a biocide, water, and an abrasive particle.

### BRIEF DESCRIPTION OF THE DRAWINGS

Embodiments will be more clearly understood from the following detailed description taken in conjunction with the accompanying drawings in which:

FIG. 1 is a partially cut-away perspective view schematically illustrating a portion of a polishing apparatus according to embodiments;

FIG. 2 is a flowchart illustrating a polishing process of a polymer-containing film according to embodiments;

FIGS. 3A, 3B, and 3C are cross-sectional views illustrating a process sequence for polishing a polymer-containing film according to embodiments;

FIG. 4 is a flowchart illustrating a method of manufacturing a semiconductor package according to embodiments;

FIGS. 5A, 5B, and 5C are cross-sectional views illustrating a process sequence for manufacturing a semiconductor package according to embodiments;

FIG. 6 is a flowchart illustrating a method of manufacturing a semiconductor package according to embodiments; and

FIGS. 7A to 7C are cross-sectional views illustrating each step of a method of manufacturing a semiconductor package according to embodiments.

### DETAILED DESCRIPTION OF THE EMBODIMENTS

Hereinafter, embodiments of the inventive concept will be described in detail with reference to the accompanying drawings. The same reference numerals are used for identical components in the drawings, and redundant explanations will be omitted.

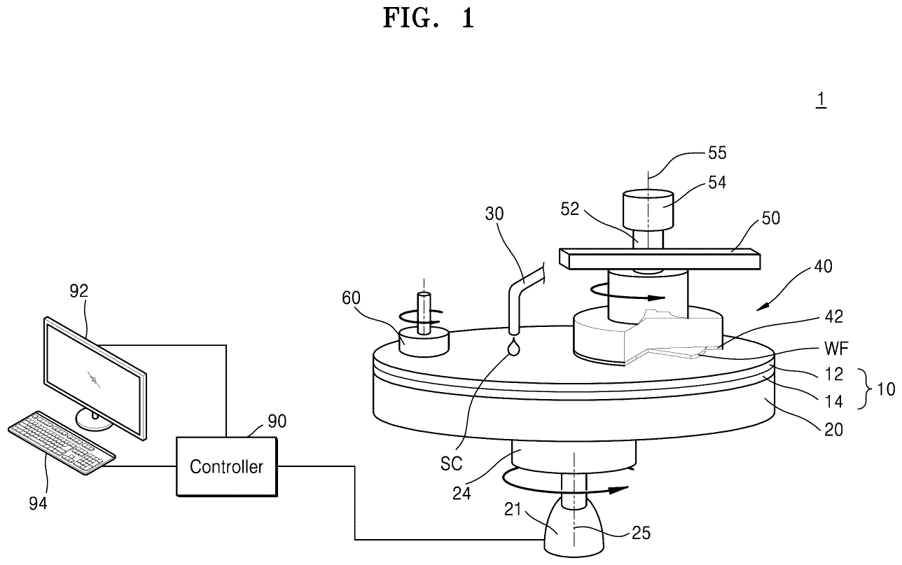

FIG. 1 is a partially cut-away perspective view schematically illustrating a portion of a polishing apparatus 1 according to embodiments.

Referring to FIG. 1, a polishing apparatus I may be used to polish the surface of a wafer WF by a chemical mechanical polishing (CMP) process. FIG. 1 illustrates a rotary-type polishing apparatus 1.

The polishing apparatus 1 may include a rotating disc-shaped platen 20. The platen 20 may be rotatably arranged about the central axis 25 of the platen 20 using a motor 21. For example, the motor 21 may rotate a drive shaft 24 to rotate the platen 20. A polishing pad 10 may be disposed on the upper surface of the platen 20. The polishing pad 10 may include a polishing layer 12 and a support layer 14. The support layer 14 may serve to support the polishing pad 10 so that it can be attached to the platen 20.

The wafer WF may have a polishing target film formed thereon, such as a metal-containing film or an insulating films. The wafer WF may include structures for forming integrated circuit devices, structures for forming Thin Film Transistor-Liquid Crystal Display (TFT-LCD), or structures that include various substrates such as glass substrates, ceramic substrates, and polymer substrates.

The polishing apparatus 1 may include a slurry port 30 for supplying a metal polishing slurry composition SC, according to embodiments, onto the polishing pad 10. The polishing apparatus 1 may further include a polishing pad conditioner 60. The polishing pad conditioner 60 may be configured to perform a dressing process to periodically polish and flatten the surface of the polishing pad 10 so that the polishing pad 10 may provide a constant polishing efficiency.

The polishing apparatus 1 may include at least one carrier head 40. A wafer WF may be loaded onto the carrier head 40. In a state where the wafer WF loaded onto the carrier head 40 is positioned to face the platen 20, the carrier head 40 may be configured to rotate while pressing the wafer WF against the platen 20. Although FIG. 1 illustrates only one carrier head 40 on the polishing pad 10, a plurality of carrier heads 40 may be arranged on the polishing pad 10. The carrier head 40 may be configured to control the pressure applied to the wafer WF.

The carrier head 40 may include a retaining ring 42 required to hold the wafer WF. The carrier head 40 may be supported by a supporting structure 50, such as a carousel or a track, and connected to a carrier head rotation motor 54 through a drive shaft 52, allowing it to rotate around the central axis 55 of the drive shaft 52.

The polishing apparatus 1 may further include a control system for controlling the rotation of the platen 20. The control system may include a controller 90 such as a general-purpose programmable digital computer, an output device 92 such as a monitor, and an input device 94 such as a keyboard. Although FIG. 1 shows a configuration in which the control system is connected only to the motor 21, this is merely an example, and the control system may also be connected to the carrier head 40 to control the pressure or rotation rate of the carrier head 40. Additionally, the control system may be connected to the slurry port 30 to control the supply of the slurry composition SC.

The slurry composition SC according to embodiments may be used to polish a polymer-containing film on a wafer WF. The slurry composition SC may include a metal ion, a nonionic polymer, a cationic chemical, a pH adjuster, a biocide, an inorganic abrasive particle, and water.

In embodiments, the slurry composition SC may be used to polish a polymer-containing film, such as a polymer-containing film including a polybenzoxazole (PBO) film, a polyhydroxyamide (PHA) film, a polyimide (PI) film, a polyamic acid (PAA) film, or a combination thereof.

In embodiments, the slurry composition SC may be used to simultaneously polish the polymer-containing film and a metal-containing film adjacent to the polymer-containing film, such as a metal-containing film including a copper (Cu) film, a Cu alloy film, a molybdenum (Mo) film, a Mo alloy film, a tungsten (W) film, a W alloy film, a cobalt (Co) film, a Co alloy film, a ruthenium (Ru) film, a Ru alloy film, or a combination thereof.

In other embodiments, the slurry composition SC may be used to simultaneously polish the polymer-containing film and an insulating film adjacent to the polymer-containing film, such as a tetraethyl orthosilicate (TEOS) film.

The metal ion included in the slurry composition SC may induce a swelling phenomenon in the polymers forming a polymer-containing film. Due to the swelling phenomenon caused by the metal ion, the bonds between the polymers forming the polymer-containing film are weakened, allowing the polymer-containing film to be easily polished by the abrasive particles.

In embodiments, the metal ion may include an iron (Fe) ion, a manganese (Mn) ion, a sodium (Na) ion, a calcium (Ca) ion, a zinc (Zn) ion, a tin (Sn) ion, a lead (Pb) ion, a silver (Ag) ion, or a combination thereof.

In embodiments, a content of the metal ion may be about 1 ppm to about 300 ppm, or any range therein, based on the total amount of the slurry composition SC. For example, the content of the metal ion may be about 1 ppm to 300 ppm, about 20 ppm to about 200 ppm, or about 50 ppm to about 150 ppm. When the content of the metal ion is less than 1 ppm, the swelling phenomenon of the polymers due to the metal ion may not occur easily. When the content of the metal ion exceeds 300 ppm, the dispersion of the abrasive particles included in the slurry composition SC may deteriorate, and thus the polishing speed using the slurry composition SC may decrease.

The cationic chemical included in the slurry composition SC may improve the dispersion of the abrasive particles included in the slurry composition SC according to embodiments. In addition, the cationic chemical may cationize the zeta potential of the abrasive particles, enabling better contact between the anionic polymers forming the polymer-containing film and the abrasive particles. As a result, the polymer-containing film may be more easily polished by the abrasive particles.

In embodiments, the cationic chemical may be a water-soluble cationic chemical. For example, the cationic chemical may include an amphoteric amino acid, an amine group, or a combination thereof. The amphoteric amino acids may include lysine, methionine, glycine, arginine, or a combination thereof. The amine group may include aminobutyric acid, 4-amino benzoic acid, picolinic acid, 1,2,4-triazole, benzotriazole, or a combination thereof.

In embodiments, the cationic chemical may be present in an amount of about 0.01 wt % to about 1 wt %, or any range therein, based on the total amount of the slurry composition SC. For example, the cationic chemical may be present in an amount of about 0.01 wt % to about 0.5 wt %, about 0.05 wt % to about 0.5 wt %, or about 0.1 wt % to about 0.5 wt % based on the total amount of the slurry composition SC. When the content of the cationic chemical is less than about 0.01 wt 9%, dispersion of the abrasive particles may not occur well. When the content of the cationic chemical exceeds about 1 wt %, the cationic chemical may bind to the surface of the polymer-containing film, thereby preventing the abrasive particles from contacting the polymers of the polymer-containing film. Accordingly, the polishing rate of the polymer-containing film may decrease.

The nonionic polymer included in the slurry composition SC may hydrophilize the hydrophobic polymers forming the polymer-containing film. As a result, the hydrophilic abrasive particles may better interact with the hydrophilized polymers. Accordingly, the polymer-containing film may be easily polished by the abrasive particles.

In embodiments, the nonionic polymer may include polyethylene glycol, polyglycerol, polyacrylamide, oxyalkylene alkyl ether, oxyalkylene alkenyl ether, oxyalkylene alkyl aryl ether, or copolymers thereof.

In embodiments, the nonionic polymer may be present in an amount of about 0.01 wt % to about 1 wt %, or any range therein, based on the total amount of the slurry composition SC. For example, the nonionic polymer may be present in an amount of about 0.01 wt % to about 0.5 wt %, about 0.05 wt % to about 0.5 wt %, or about 0.1 wt % to about 0.5 wt % based on the total amount of the slurry composition SC. When the content of the nonionic polymer is less than about 0.01 wt %, the polymers forming the polymer-containing film may not be hydrophilized. When the content of the nonionic polymer exceeds about 1 wt %, the nonionic polymer may bind to the surface of the polymer-containing film, thereby preventing the abrasive particles from contacting the polymers of the polymer-containing film. Accordingly, the polishing rate of the polymer-containing film may decrease.

In embodiments, the polishing rate of the slurry composition SC for a polymer-containing film may be about 5000 A/min or more, and the polishing rate of the slurry composition SC for a metal-containing film or an insulating film may be about 500 A/min or less. For example, the polishing rate for a polybenzoxazole (PBO)-containing film of the slurry composition SC may be about 5000 Å/min or more, and the polishing rate for a Cu-containing film or an insulating film of the slurry composition SC may be about 500 Å/min or less. Accordingly, in a polishing process using the slurry composition SC according to embodiments, when simultaneously polishing a polymer-containing film and a metal-containing film, or a polymer-containing film and an insulating film, the polymer-containing film may be polished with a higher selectivity relative to the metal-containing film or the insulating film.

The abrasive particles included in the slurry composition SC may serve to polish the polymer-containing film in the polishing process. In embodiments, the abrasive particles may be inorganic oxide abrasive particles. For example, the abrasive particles may include silica, alumina, ceria, titania, zirconia, magnesia, germania, mangania, or a combination thereof.

The pH adjuster included in the slurry composition SC may function to adjust the slurry composition SC to have a pH selected within a range of about 2 to about 11.

In embodiments, the pH adjuster may include, but is not limited to, potassium hydroxide, acetic acid, nitric acid, hydrogen chloride, ammonium hydroxide, sodium hydroxide, tetramethylammonium hydroxide, or a combination thereof.

In embodiments, the slurry composition SC may have a pH selected within the range of about 2 to about 11, or any range therein. For example, the slurry composition SC may have a pH of about 4 to about 10, or a pH of about 5 to about 8. In order to control the pH of the slurry composition to a desired value, an appropriate amount of the pH adjuster including an acid solution and/or an alkaline solution may be used. In the slurry composition SC, the pH adjuster may be included in an amount necessary to adjust the slurry composition SC to have a required pH, and is not particularly limited.

The water included in the slurry composition SC may be deionized water. A content of the water included in the slurry composition SC is not particularly limited, and may be included as a balance in the slurry composition SC, along with the main components including the metal ion, the cationic chemical, the nonionic polymer, the abrasive particle, and the pH adjuster.

The slurry composition SC according to embodiments may further include a biocide. The biocide may function to prevent the slurry composition SC and the polishing target to which the slurry composition SC is applied from being contaminated with microorganisms.

In embodiments, the biocide may be, but is not limited to, an organotin compound, a salicylanilide, formaldehyde, a quaternary ammonium compound, 2-bromo-2-nitropropane-1,3-diol (bronopol), 2,2-dibromo-3-nitrilopropionamide (DBNPA), an isothiazolone, a carbamate, a quaternary phosphonium salt (e.g., tetrakis (hydroxymethyl)-phosphonium sulfate (THPS)), sodium chloride, sodium hypochlorite, trichloroisocyanuric acid, dichloroisocyanuric acid, calcium hypochlorite, lithium hypochlorite, chlorine dioxide, ozone, hydrogen peroxide, or a combination thereof.

When the biocide is included in the slurry composition, a content of the biocide may be about 0.001 wt % to about 10 wt % based on the total amount of the slurry composition, or any range therein. In embodiments, the content of the biocide may be from about 0.001 wt % to about 5 wt %, from about 0.001 wt % to about 3 wt %, or from about 0.001 wt % to about 1 wt %.

The slurry composition according to embodiments may include a metal ion, a cationic chemical, and a nonionic polymer. The metal ion may weaken the bonds between the polymers forming the polymer-containing film, the cationic chemical may enhance the dispersion of abrasive particles included in the slurry composition, and the nonionic polymer may hydrophilize the polymers forming the polymer-containing film. As a result, the polishing rate of the polymer-containing film may increase.

Hereinafter, examples are provided to describe the evaluation of the effects of the slurry composition according to embodiments, in comparison with a comparative example, with reference to Table 1.

TABLE 1

| | Comparative | Comparative | Comparative | Comparative | | | |
|---|---|---|---|---|---|---|---|
| | Example 1 | Example 2 | Example 3 | Example 4 | Example 1 | Example2 | Example 3 |
| Zeta potential | Positive | Negative | Positive | Positive | Positive | Positive | Positive |
| of abrasive | | | | | | | |
| particles | | | | | | | |
| nonionic | A | A | A | — | A | A | A |
| polymer | | | | | | | |
| Metal ion | — | — | Fe | Fe | Fe | Na | Mn |
| Content(ppm) | — | — | 350 | 200 | 200 | 200 | 200 |
| Polishing rate of | 352 | 12 | 7,358 | 3,125 | 9,352 | 7,855 | 8,125 |
| polymer(A/min) | | | | | | | |
| Dispersion | X | X | ◯ | X | X | X | X |
| (Partice | | | | | | | |
| aggretation) | | | | | | | |

In Table 1, slurry compositions according to embodiments (Examples) and slurry compositions according to comparative examples (Comparative Examples) were used to polish a polymer-containing film, and the polishing rate of the polymer-containing film was evaluated.

In Table 1, Comparative Example 1, Comparative Example 2, Comparative Example 3, Comparative Example 4, Example 1, Example 2, and Example 3 include abrasive particles. Additionally, Comparative Example 1, Comparative Example 3, Comparative Example 4, Example 1, Example 2, and Example 3 include lysine as a cationic chemical, and Comparative Example 2 includes an anionic chemical. Additionally, Comparative Example 1, Comparative Example 2, Comparative Example 3, Example 1, Example 2, and Example 3 include polyethylene glycol as a nonionic polymer, and Comparative Example 4 does not include a nonionic polymer. Additionally, Comparative Example 3, Comparative Example 4, and Example 1 include iron as the metal ion, Example 2 includes sodium as the metal ion, Example 3 includes manganese as a metal ion, and Comparative Example 1 and Comparative Example 2 do not include a metal ion. The polymer-containing film, which is the polishing target film, is made of polybenzoxazole (PBO).

When comparing Example 1, Example 2, and Example 3 with Comparative Example 1, it may be observed that the polishing rates of polymer-containing films were significantly higher in Examples 1, 2, and 3 when the slurry composition included metal ions. This is believed to be because the metal ions in the slurry composition induce a swelling phenomenon in the polymers forming the polymer-containing film.

When comparing Example 1 and Comparative Example 3, it may be observed that the polishing rate of the polymer-containing film by the slurry composition of Example 1 is relatively higher than the polishing rate of the polymer-containing film by the slurry composition of Comparative Example 3. This is believed to be because the slurry composition in Comparative Example 3 includes a metal ion content exceeding 300 ppm, which reduces the dispersion of abrasive particles due to the excessive metal ions.

When comparing Comparative Example 1 and Comparative Example 2, it may be observed that the polishing rate of the polymer-containing film by the slurry composition of Comparative Example 1 is relatively higher than the polishing rate of the polymer-containing film by the slurry composition of Comparative Example 2. This is believed to be because the cationic chemical included in the slurry composition of Comparative Example I cationizes the zeta potential of the abrasive particles, allowing better contact between the anionic polymers forming the polymer-containing film and the abrasive particles.

When comparing Example 1 and Comparative Example 4, it may be confirmed that the inclusion of a nonionic polymer in the slurry composition significantly increases the polishing rate of the polymer-containing film. This is believed to be because the nonionic polymer in the slurry composition hydrophilizes the polymers constituting the polymer-containing film, thereby enabling the abrasive particles in the slurry composition to make better contact with the hydrophilized polymers.

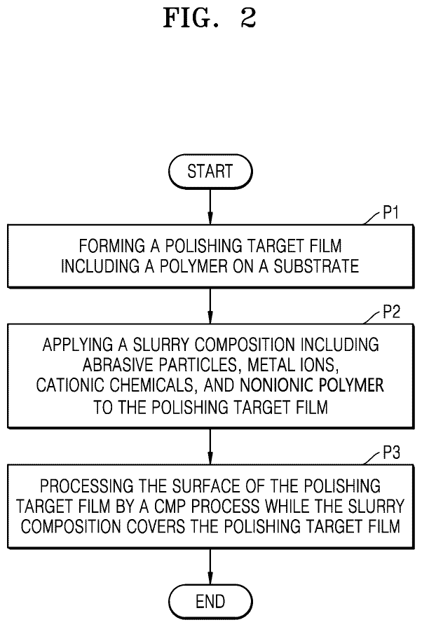

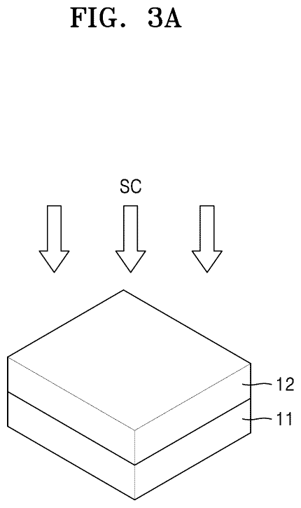

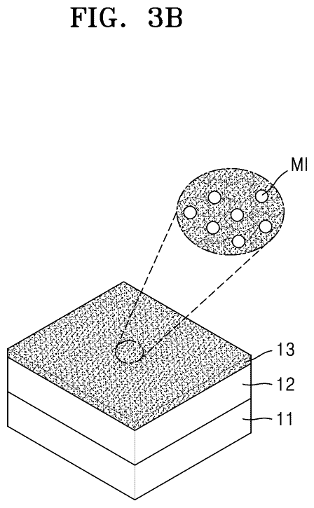

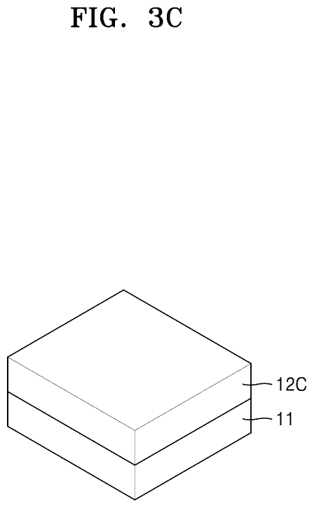

FIG. 2 is a flow chart illustrating a polishing process of a polymer-containing film according to embodiments. FIGS. 3A, 3B, and 3C are cross-sectional views illustrating a process sequence for polishing a polymer-containing film according to embodiments.

Referring to FIGS. 2, 3A, and 3B, a polymer-containing film 12 may first be formed on a substrate 11 (P1). The substrate 11 may include a semiconductor such as Si or Ge, or a compound semiconductor such as SiGe, SiC, GaAs, InAs, or InP. The substrate 11 may include a conductive region (not shown). The conductive region may include a well doped with impurities, a structure doped with impurities, or a conductive layer.

The polymer-containing film 12 may include a polybenzoxazole (PBO) film, a polyhydroxyamide (PHA) film, a polyimide (PI) film, a polyamic acid (PAA) film, or a combination thereof.

Next, a slurry composition SC may be provided on the polymer-containing film 12 (P2). The slurry composition SC may include an abrasive particle, a metal ion MI, a cationic chemical, and a nonionic polymer. The detailed composition of the slurry composition SC may be as described above.

The metal ions MI included in the slurry composition SC may induce a swelling phenomenon in the polymers forming the polymer-containing film 12, which is the polishing target film. As a result, a swelling layer 13 may form on the surface of the polymer-containing film 12.

Referring to FIGS. 2 and 3C, a polishing process may be performed to remove the swelling layer 13 (FIG. 3B). Consequently, a polymer-containing film 12C with a polished upper portion may be formed.

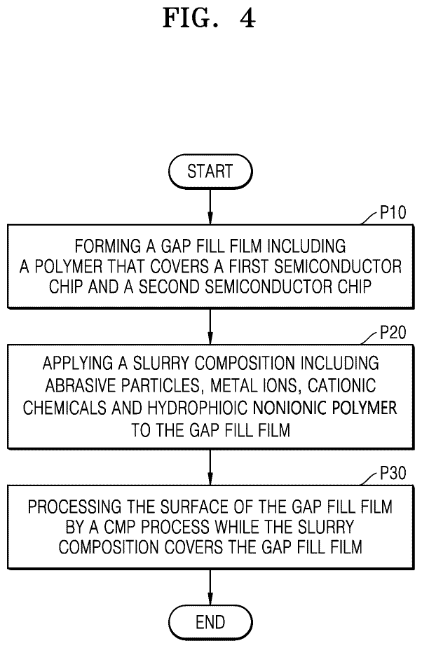

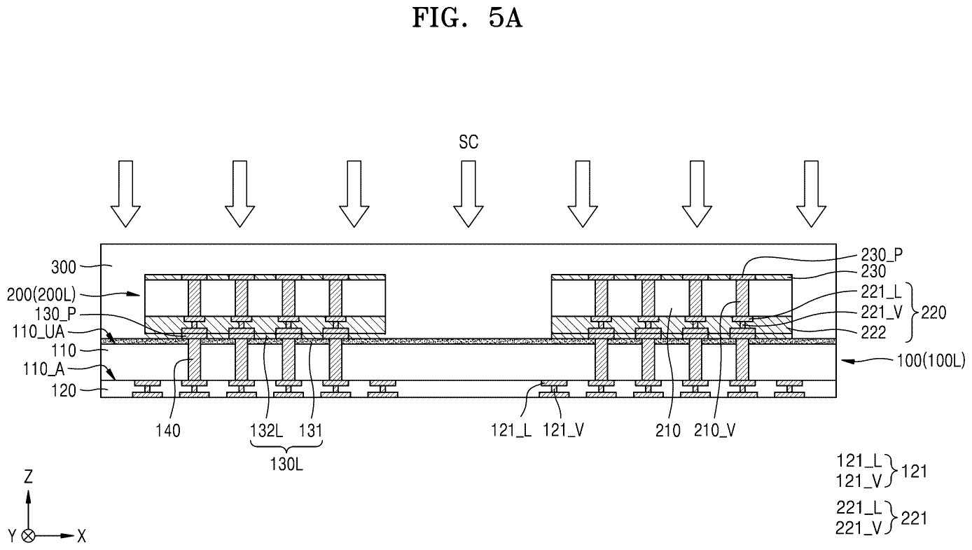

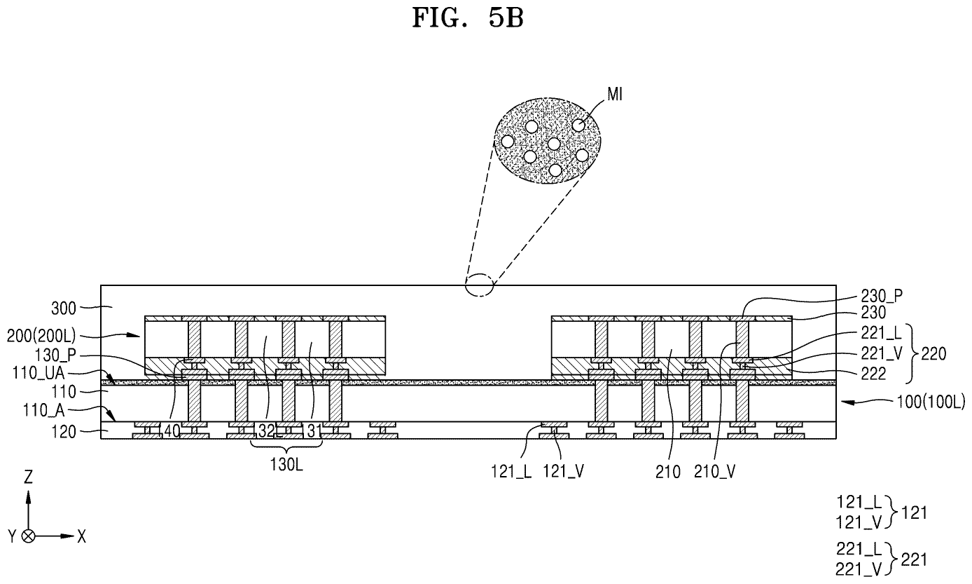

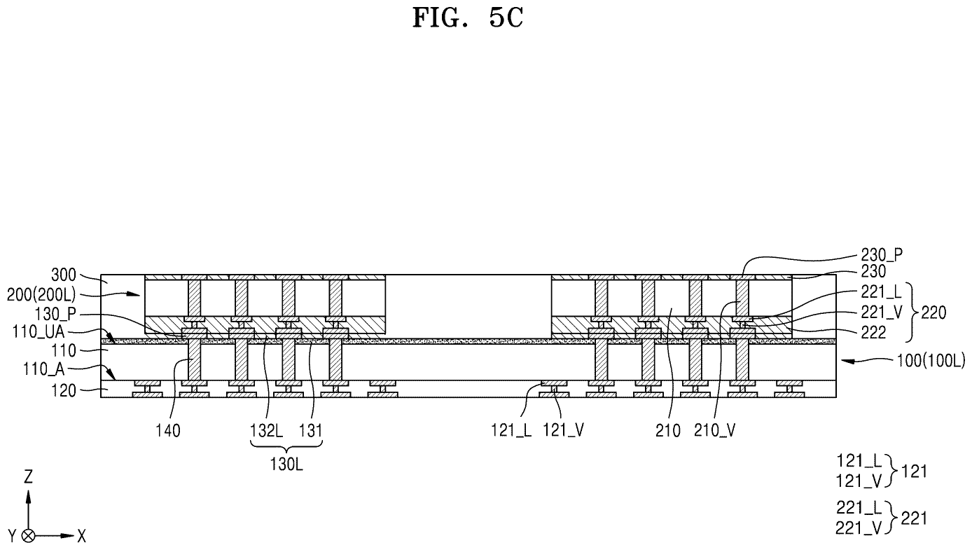

FIG. 4 is a flowchart illustrating a method of manufacturing a semiconductor package according to embodiments. FIGS. 5A, 5B, and 5C are cross-sectional views illustrating a process sequence for manufacturing a semiconductor package according to embodiments.

Referring to FIG. 4 and FIG. 5A, first, a gap fill film 300 may first be formed to cover the first semiconductor chip 100L, and the second semiconductor chip 200 mounted on the first semiconductor chip 100L (P10). The first semiconductor chip 100L may include a first semiconductor substrate 110, a first wiring structure 120, a plurality of first through electrodes 140, a plurality of first chip pads 130_P, and a first passivation layer 130L.

The first semiconductor substrate 110 may include a semiconductor material such as silicon (Si). Alternatively, the first semiconductor substrate 110 may include a semiconductor material such as germanium (Ge).

The first semiconductor substrate 110 may include an active surface 100_A and an inactive surface 110_UA, which faces the active surface 100_A in a vertical direction (Z direction). A semiconductor device containing a plurality of individual devices of various types may be formed on the active surface 110_A of the first semiconductor substrate 110. The plurality of individual devices in the first semiconductor substrate 110 may include various microelectronic devices, including metal-oxide-semiconductor field-effect transistors (MOSFETs) such as complementary metal-oxide-semiconductor (CMOS) transistors, system large-scale integrations (LSIs), image sensors such as CMOS imaging sensors (CISs), micro-electro-mechanical systems (MEMS), active devices, passive devices, and more.

The first wiring structure 120 may be positioned on the active surface 100_A of the first semiconductor substrate 110. The first wiring structure 120 may electrically connect the semiconductor device located on the surface 110_A of the first semiconductor substrate 110. The first wiring structure 120 may include a first wiring pattern 121 and a first wiring insulating layer 122 surrounding the first wiring pattern 121. The first wiring pattern 121 may include a first wiring line 121_L extending in a first horizontal direction (X direction) and a first wiring via 121_V extending from the first wiring line 121_L in a vertical direction (Z direction). The first wiring pattern 121 may electrically connect to a plurality of the individual devices in the first semiconductor substrate 110.

The plurality of first through-hole electrodes 140 may extend vertically (Z direction) from the active surface 100_A of the first semiconductor substrate 110 to the inactive surface 110_UA. Each of the plurality of first through-hole electrodes 140 may penetrate a portion of the first semiconductor substrate 110. Each of the plurality of first through-hole electrodes 140 may be electrically connected to the first wiring structure 120.

The plurality of first chip pads 130_P may be positioned on the inactive surface 110_UA of the first semiconductor substrate 110. The lower surface of each of the plurality of first chip pads 130_P may be in contact with each of the corresponding plurality of first through electrodes 140, and the upper surface of each of the first chip pads 130_P may be exposed externally.

Each of the plurality of first chip pads 130_P may be electrically connected to each of the plurality of first through electrodes 140. The plurality of first chip pads 130_P and the plurality of first through-hole electrodes 140 may correspond one-to-one in the vertical direction (Z direction).

In embodiments, the plurality of first through-hole electrodes 140 and the plurality of first chip pads 130_P may each be made of copper, nickel, stainless steel, or beryllium copper.

The first passivation layer 130L may be located on the inactive surface 110_UA of the first semiconductor substrate 110. The first passivation layer 130L may surround the plurality of first chip pads 130_P. The first passivation layer 130L may include an insulating layer 131 and an oxide layer 132L. The oxide layer 132L may be located on the insulating layer 131. The lower surface of the insulating layer 131 may be in contact with the first semiconductor substrate 110, while the upper surface of the insulating layer 131 may be in contact with the oxide layer 132L. For example, the insulating layer 131 may include silicon nitride, and the oxide layer 132L may include silicon oxide.

The plurality of second semiconductor chips 200 may be arranged on the first semiconductor chip 100 so as to be spaced apart horizontally from one another. Each of the plurality of second semiconductor chips 200 may include a second semiconductor substrate 210 and a second wiring structure 220.

The second semiconductor substrate 210 may include an active surface and an inactive surface opposite thereto. For example, the second semiconductor substrate 210 may include a semiconductor material such as silicon (Si) or germanium (Ge). The second semiconductor substrate 210 may also include compound semiconductor materials such as silicon carbide (SiC), gallium arsenide (GaAs), indium arsenide (InAs), and indium phosphide (InP).

On the active surface of the second semiconductor substrate 210, a semiconductor device containing various types of individual devices may be formed. The individual devices in the second semiconductor substrate 210 may include various microelectronic devices, including metal-oxide-semiconductor field-effect transistors (MOSFETs) such as complementary metal-oxide-semiconductor (CMOS) transistors, system large-scale integrations (LSIs), image sensors such as CMOS imaging sensors (CISs), micro-electro-mechanical systems (MEMS), active devices, passive devices, and more.

The second wiring structure 220 may be positioned on the active surface of the second semiconductor substrate 210. The second wiring structure 220 may electrically connect to the individual devices of the second semiconductor substrate 210.

The second wiring structure 220 may include a second wiring pattern 221 and a second wiring insulating layer 222 surrounding the second wiring pattern 221. The second wiring pattern 221 may include a second wiring line 221_L and a second wiring via 221_V. The second wiring pattern 221 may have a second wiring line 221_L extending in a first horizontal direction (X direction) and a second wiring via 221_V extending in a vertical direction (Z direction) from the second wiring lines 221_L.

The plurality of second semiconductor chips 200 may each further include a plurality of second through electrodes 210_V extending from the inactive surface to the active surface of the second semiconductor substrate 210. The plurality of second through electrodes 210_V of the second semiconductor chip 200 may be electrically connected to the second wiring structure 220 of the second semiconductor chip 200.

The second semiconductor chip 200 may further include a plurality of second backside pads 230_P located on the inactive surface of the second semiconductor substrate 210. The plurality of second backside pads 230_P may be positioned on the plurality of second through electrodes 210_V.

In an embodiment, the first semiconductor chip 100L and the second semiconductor chip 200 may be bonded together through hybrid bonding. However, the inventive concept is not limited to these.

The gap fill film 300 may cover the upper surface of the first semiconductor chip 100L and the plurality of second semiconductor chips 200. The gap filler film 300 may be a polymer-containing film. For example, the gap fill film 300 may be made of a polymer-containing film such as a polybenzoxazole (PBO) film, a polyhydroxyamide (PHA) film, a polyimide (PI) film, a polyamic acid (PAA) film, or a combination thereof.

Next, the slurry composition SC may be applied to the gap fill film 300 (P20). The slurry composition SC may include an abrasive particle, a metal ion MI, a cationic chemical, and a nonionic polymer. The detailed composition of the slurry composition SC may be as described earlier.

The metal ions MI included in the slurry composition SC may induce a swelling phenomenon in the polymers constituting the gap-fill film 300, which serves as the polishing target (FIG. 5B).

Referring to FIGS. 4 and 5C, a polishing process may be performed to remove a portion of the gap fill film 300 (P30). In FIG. 5C, after the polishing process, the upper surface of the gap fill film 300 is shown to be at the same vertical level as the upper surfaces of the plurality of second semiconductor chips 200. However, the inventive concept is not limited to this configuration.

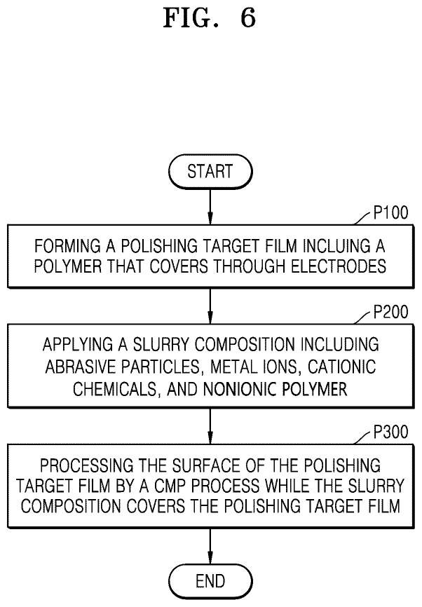

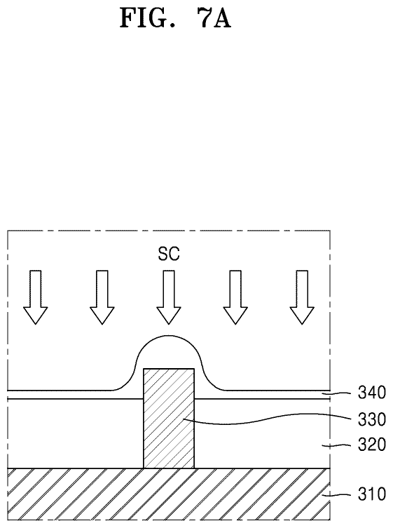

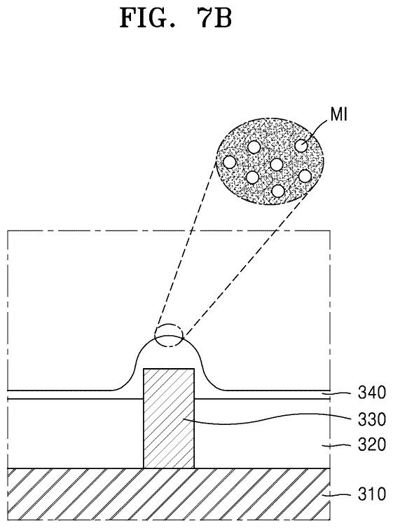

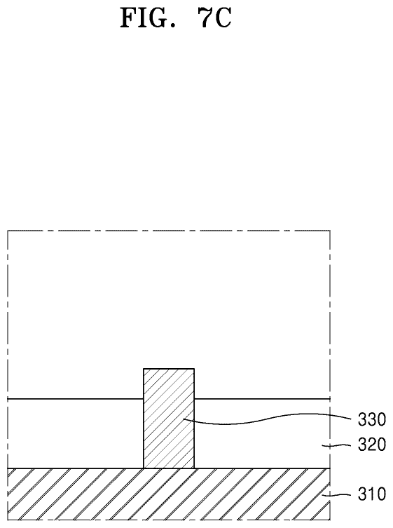

FIG. 6 is a flowchart illustrating a method for manufacturing a semiconductor package according to embodiments. FIGS. 7A and 7B are cross-sectional views illustrating each step of a method of manufacturing a semiconductor package according to embodiments.

Referring to FIGS. 6, 7A, and 7B, a polymer-containing film 340 may be formed to cover the wiring layer 310 and the through electrode 330 placed on the wiring layer 310 (P100).

The wiring layer 310 may constitute the wiring layer of a semiconductor chip in the semiconductor package. The through electrode 330 may be electrically connected to the wiring layer 310. At least a portion of the sidewalls of the through electrode 330 may be surrounded by an insulating layer 320. The insulating layer 320 may include silicon nitride, silicon oxide, or a combination thereof. The polymer-containing film 340 may cover the through electrode 330 and the insulating layer 320. The polymer-containing film 340 may be made of a polybenzoxazole (PBO) film, a polyhydroxyamide (PHA) film, a polyimide (PI) film, a polyamic acid (PAA) film, or a combination thereof.

Next, a slurry composition SC may be applied to the polymer-containing film 340 (P200). The slurry composition SC may include an abrasive particle, a metal ion MI, a cationic chemical, and a nonionic polymer. The detailed composition of the slurry composition SC may be as described above.

The metal ions MI included in the slurry composition SC may induce a swelling phenomenon in the polymers forming the polymer-containing film 340 (FIG. 7B).

Referring to FIGS. 6 and 7C, a polishing process may be performed to remove the polymer-containing film 340 (see FIG. 7B) (P300). During the P300 process, the polymer-containing film 340 (see FIG. 7B) may be completely removed, and a portion of the through electrode 330 may also be polished. However, as previously described, since the slurry composition SC according to embodiments exhibits higher selectivity for the polymer-containing film 340, the polymer-containing film 340 may be removed with higher selectivity relative to the metal-containing through electrode 330.

As described above, embodiments have been disclosed with reference to the drawings and the specification. Although specific terms have been used to describe the embodiments, these terms are used only to explain the inventive concept and are not intended to limit the scope of the inventive concept as defined by the claims. Therefore, those skilled in the art will understand that various modifications and equivalent alternative embodiments are possible without departing from the scope of the inventive concept. Therefore, the true technical protection scope of the inventive concept should be determined by the technical idea set forth in the appended claims.

While the inventive concept has been particularly shown and described with reference to embodiments thereof, it will be understood that various changes in form and details may be made therein without departing from the spirit and scope of the following claims.

What is claimed is:

1. A slurry composition for polishing a polymer-containing film, comprising
a metal ion,
a cationic chemical,
a nonionic polymer, and
an abrasive particle.

2. The slurry composition of claim 1,
wherein the metal ion comprises Fe, Mn, Na, Ca, Zn, Sn, Pb, Ag, or a combination thereof.

3. The slurry composition of claim 1,
wherein a content of the metal ion is about 1 ppm to about 300 ppm based on the total amount of the slurry composition.

4. The slurry composition of claim 1,
wherein the nonionic polymer comprises polyethylene glycol, polyglycerol, polyacrylamide, oxyalkylene alkyl ether, oxyalkylene alkenyl ether, oxyalkylene alkyl aryl ether, or a copolymer thereof.

5. The slurry composition of claim 1,
wherein a content of the nonionic polymer is about 0.01 wt % to about 1 wt % based on the total amount of the slurry composition.

6. The slurry composition of claim 1,
wherein the cationic chemical comprises an amphoteric amino acid, an amine group, or a combination thereof.

7. The slurry composition of claim 6,
wherein the amphoteric amino acid comprises lysine, methionine, glycine, arginine, or a combination thereof, and/or the amine group comprises aminobutyric acid, 4-amino benzoic acid, picolinic acid, 1,2,4-triazole, benzotriazole, or a combination thereof.

8. The slurry composition of claim 1,
wherein a content of the cationic chemical is about 0.01 wt % to about 1 wt % based on the total amount of the slurry composition.

9. The slurry composition of claim 1,
wherein the polymer-containing film which is polished by the slurry composition consists of a polybenzoxazole (PBO) film, a polyhydroxyamide (PHA) film, a polyimide (PI) film, a polyamic acid (PAA) film, or a combination thereof.

10. The slurry composition of claim 1,
wherein a polishing rate of the polymer-containing film with respect to the slurry composition is about 5000 Å/min or more, and a polishing rate of the metal-containing film or insulating film with respect to the slurry composition is about 500 Å/min or less.

11. A method of manufacturing a semiconductor package, comprising:
forming a gap fill film covering a first semiconductor chip and a plurality of second semiconductor chips horizontally spaced apart from each other on the first semiconductor chip;
applying a slurry composition to the gap fill film; and
polishing the gap fill film,
wherein the gap fill film is a polymer-containing film, and
wherein the slurry composition comprises a metal ion, a cationic chemical, a nonionic polymer, and abrasive particles.

12. The method of claim 11,
wherein the metal ion comprises Fe, Mn, Na, Ca, Zn, Sn, Pb, Ag, or a combination thereof, and a content of the metal ion is about 1 ppm to about 300 ppm based on the total amount of the slurry composition.

13. The method of claim 11,
wherein the nonionic polymer comprises polyethylene glycol, polyglycerol, polyacrylamide, oxyalkylene alkyl ether, oxyalkylene alkenyl ether, oxyalkylene alkyl aryl ether, or copolymers thereof, and a content of the nonionic polymer is about 0.01 wt % to about 1 wt % based on the total amount of the slurry composition.

14. The method of claim 11,
wherein the cationic chemical comprises an amphoteric amino acid, an amine group, or a combination thereof, and a content of the cationic chemical is about 0.01 wt % to about 1 wt % based on the total amount of the slurry composition.

15. The method of claim 11,
wherein the gap fill film consists of a polybenzoxazole (PBO) film, a polyhydroxyamide (PHA) film, a polyimide (PI) film, a polyamic acid (PAA) film, or a combination thereof.

16. A slurry composition used for surface treatment of a polymer-containing film by a chemical mechanical polishing (CMP) process, the slurry composition comprising
a metal ion, a cationic chemical, a nonionic polymer, a pH adjuster, a biocide, water, and abrasive particles.

17. The slurry composition of claim 16,
wherein the metal ion comprises Fe, Mn, Na, Ca, Zn, Sn, Pb, Ag, or a combination thereof, and a content of the metal ion is about 1 ppm to about 300 ppm based on the total amount of the slurry composition.

18. The slurry composition of claim 16,
wherein the nonionic polymer comprises polyethylene glycol, polyglycerol, polyacrylamide, oxyalkylene alkyl ether, oxyalkylene alkenyl ether, oxyalkylene alkyl aryl ether, or a copolymer thereof, and a content of the nonionic polymer is about 0.01 wt % to about 1 wt % based on the total amount of the slurry composition.

19. The slurry composition of claim 16,
wherein the cationic chemical comprises an amphoteric amino acid, an amine group, or a combination thereof, and a content of the cationic chemical is about 0.01 wt % to about 1 wt % based on the total amount of the slurry composition.

20. The slurry composition of claim 16,
wherein the abrasive particles comprise silica, alumina, ceria, titania, zirconia, magnesia, germania, mangania, or a combination thereof.
